(19) United States
(12) Patent Application Publication
(10) Pub. No.: US 2024/0321852 A1
(43) Pub. Date: Sep. 26, 2024

(54) SEMICONDUCTOR STORAGE DEVICE

(71) Applicant: Kioxia Corporation, Tokyo (JP)

(72) Inventors: Ryosuke MATSUO, Yokkaichi Mie (JP); Kohei YOSHIMI, Yokkaichi Mie (JP); Hiroomi NAKAJIMA, Setagaya Tokyo (JP)

(21) Appl. No.: 18/595,329

(22) Filed: Mar. 4, 2024

(30) Foreign Application Priority Data
Mar. 24, 2023 (JP) 2023-047477

(51) Int. Cl. H01L 25/18; H01L 23/00; H01L 23/498; H10B 80/00

(52) U.S. Cl. CPC H01L 25/18; H01L 23/49838; H01L 24/08; H10B 80/00; H01L 2224/08147; H01L 2924/30101

(57) ABSTRACT

A semiconductor storage device according to an embodiment includes a first chip with memory cells, and a second chip that controls operations performed on the memory cells. The first chip includes a stacked body including a plurality of conductive layers stacked in a first direction, a plurality of pillar structures, a plurality of partitions extending within the stacked body in the first direction and a second direction intersecting the first direction, a pad portion, and a connection structure that electrically connects the pad portion and a circuit provided in the second chip, and includes a plate-shaped part extending in the first direction and one of the second direction and a third direction intersecting the first and second directions.

### CROSS-REFERENCE TO RELATED APPLICATION(S)

This application is based upon and claims the benefit of priority from Japanese Patent Application No. 2023-047477, filed Mar. 24, 2023, the entire contents of which are incorporated herein by reference.

### FIELD

Embodiments described herein relate generally to a semiconductor storage device.

### BACKGROUND

A semiconductor storage device has a structure in which a memory chip that performs a memory operation and a control chip that controls the memory operation of the memory chip are bonded to each other. The semiconductor storage device formed by such bonded chips includes a structure in which a circuit provided in the control chip is electrically connected to the outside via a pad portion provided in the memory chip.

### DESCRIPTION OF THE DRAWINGS

FIG. 1 is a cross-sectional view schematically illustrating a configuration of a semiconductor storage device according to a first embodiment.

FIG. 2 is a plane pattern view schematically illustrating a configuration of a memory chip provided in the semiconductor storage device according to the first embodiment.

FIGS. 3-4 are cross-sectional views schematically illustrating a configuration of a pillar structure provided in the semiconductor storage device according to the first embodiment.

FIGS. 5-8 are plane pattern views schematically illustrating different configurations of a connection structure provided in the semiconductor storage device according to the first embodiment.

FIG. 9 is a cross-sectional view schematically illustrating a configuration of the semiconductor storage device according to a second embodiment.

FIG. 10 is a plane pattern view schematically illustrating a configuration of the memory chip provided in the semiconductor storage device according to the second embodiment.

### DETAILED DESCRIPTION

Embodiments provide a semiconductor storage device capable of providing a low resistance electrical connection between a circuit provided in a control chip and a pad portion provided in a memory chip.

In general, according to one embodiment, a semiconductor storage device according to an embodiment includes a first chip that has a first main surface and a second main surface and includes memory cells, and a second chip that is bonded to the first main surface of the first chip and is configured to control operations performed on the memory cells of the first chip. The first chip includes a stacked body including a plurality of conductive layers that are stacked in a first direction, a plurality of pillar structures that each include a semiconductor layer extending within the stacked body in the first direction, a plurality of partitions extending within the stacked body in the first direction and a second direction that intersects with the first direction to divide the stacked body in a third direction that intersects with the first direction and the second direction, a pad portion that is exposed at the second main surface, and a connection structure that electrically connects the pad portion and a circuit provided in the second chip, and includes a first plate-shaped part that extends in the first direction and one of the second direction and the third direction.

Hereinafter, embodiments will be described with reference to the drawings.

### First Embodiment

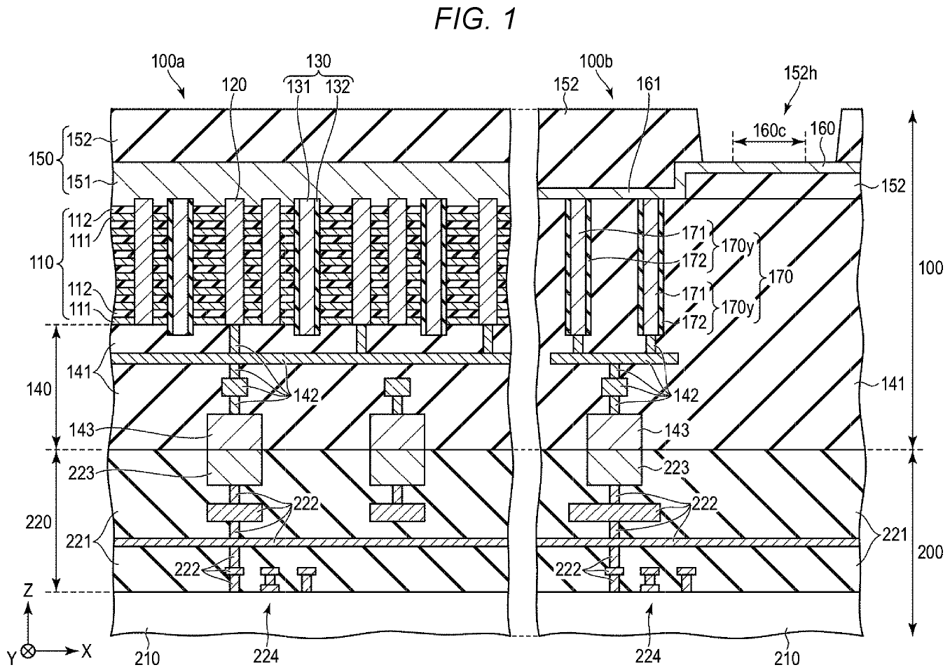

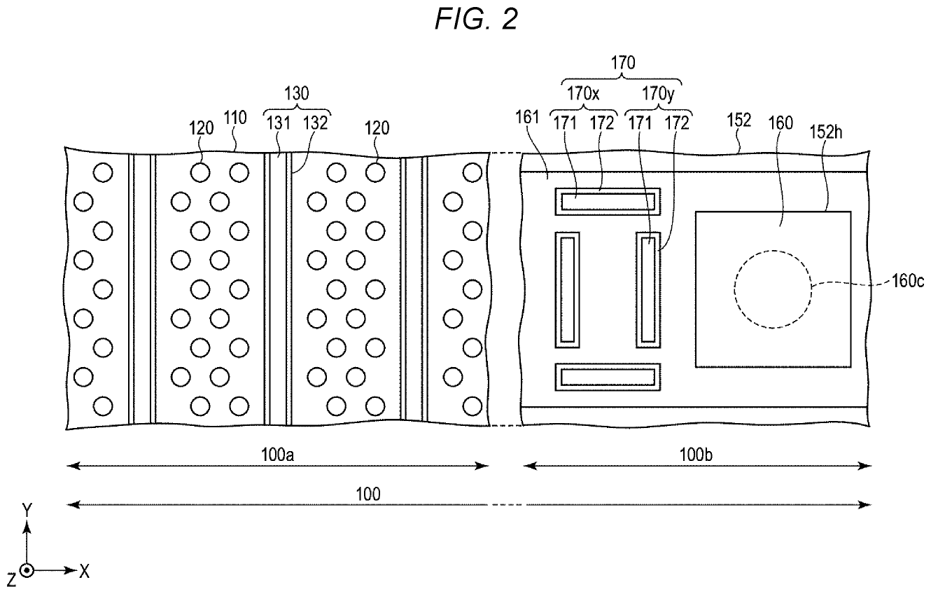

FIG. 1 is a cross-sectional view schematically illustrating a configuration of a NAND-type nonvolatile semiconductor storage device having a three-dimensional structure according to a first embodiment. FIG. 2 is a plane pattern view schematically illustrating a configuration of a memory chip 100 provided in the semiconductor storage device illustrated in FIG. 1 and a plane pattern view of a region corresponding to the region illustrated in FIG. 1.

An X-direction, a Y-direction, and a Z-direction indicated in FIG. 1 or the like are directions that intersect each other. Specifically, the X-direction, the-Y direction, and the-Z direction are orthogonal to each other.

The semiconductor storage device according to the present embodiment includes the memory chip 100 that performs a memory operation and a control chip 200 that controls the memory operation of the memory chip 100. The first main surface of the memory chip 100 and the first main surface of the control chip 200 are bonded to each other to form one semiconductor chip.

The memory chip 100 includes a memory region 100a and a connection region 100b.

The memory region 100a includes a stacked body 110, a plurality of pillar structures 120, a plurality of partitions 130, a lower region 140, an upper region 150 and the like.

The stacked body 110 includes a plurality of conductive layers 111 that are stacked in the Z-direction apart from each other. More specifically, the stacked body 110 includes the plurality of conductive layers 111 and a plurality of insulation layers 112 that are alternately stacked in the Z-direction.

Each conductive layer 111 functions as a word line or a select gate line for a NAND string. The NAND string has a structure in which one or more lower select transistors, one or more upper select transistors, and a plurality of memory cells provided between one or more lower select transistors and one or more upper select transistors are stacked in the Z-direction. The conductive layer 111 is made of a metal material such as tungsten and the insulation layer 112 is made of an insulation material such as silicon oxide. One or more conductive layers 111 including the bottommost of the conductive layers 111 function as lower select gate lines and one or more conductive layers 111 including the topmost of the conductive layers 111 function as upper select gate lines. In addition, the plurality of conductive layers 111 provided between one or more conductive layers 111 including the bottommost conductive layer and one or more conductive layers 111 including the topmost conductive layer function as word lines.

The plurality of pillar structures 120 are arranged in the X-direction and the Y-direction, and each pillar structure 120 extends within the stacked body 110 in the Z-direction.

Each pillar structure 120 is used for the NAND string. That is, the NAND string is formed by the pillar structure 120 and the plurality of conductive layers 111 surrounding the pillar structure 120. More specifically, the NAND string including one or more upper select transistors, memory cells, and one or more lower select transistors is formed with the pillar structure 120 and respective conductive layers 111 that function as the upper select gate lines, word lines, and the lower select gate lines.

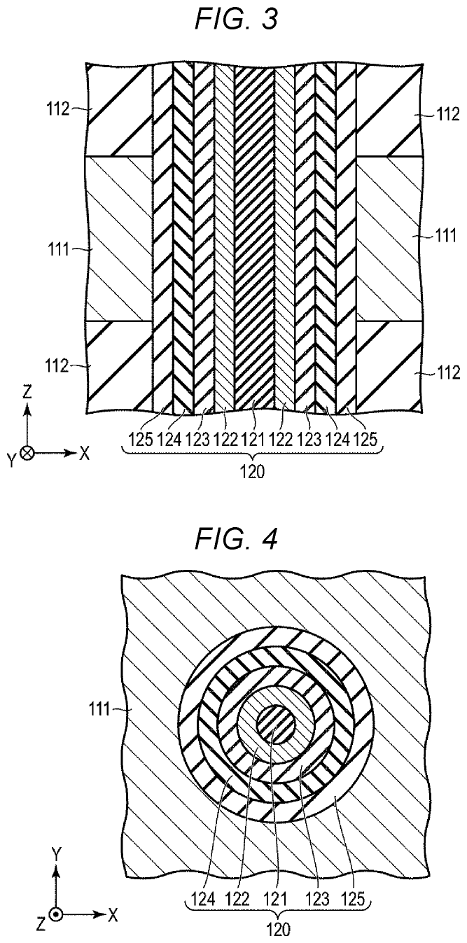

Each of FIG. 3 and FIG. 4 is a cross-sectional view schematically illustrating a configuration of the pillar structure 120. FIG. 3 is a cross-sectional view parallel to the Z-direction, and FIG. 4 is a cross-sectional view perpendicular to the Z-direction.

As illustrated in FIG. 3 and FIG. 4, the pillar structure 120 includes a core insulation layer 121, a semiconductor layer 122 surrounding the side surface of the core insulation layer 121, a tunnel insulation layer 123 surrounding the side surface of the semiconductor layer 122, a charge storage layer 124 surrounding the side surface of the tunnel insulation layer 123, and a block insulation layer 125 surrounding the side surface of the charge storage layer 124.

The plurality of partitions 130 are arranged in the X-direction, and each partition 130 extends within the stacked body 110 in the Y-direction and the Z-direction. The plurality of pillar structures 120 are divided into a plurality of blocks in the X-direction by the plurality of partitions 130. Each partition 130 has a plate-shaped structure, and includes a conductive part 131 made of a conductive material such as a metal material and an insulation part 132 made of an insulation material and provided along the side surface of the conductive part 131. Both the conductive part 131 and the insulation part 132 extend in the Y-direction and the Z-direction.

The partition 130 is also used for processing to replace a sacrificial layer provided in a preliminary stacked body with the conductive layer 111 provided in the stacked body 110. That is, the preliminary stacked body has a structure in which a plurality of sacrificial layers and the plurality of insulation layers 112 are alternately stacked, and the stacked body 110 in which the plurality of conductive layers 111 and the plurality of insulation layers 112 are alternately stacked is formed by replacing the plurality of sacrificial layers with the plurality of conductive layers 111. The partition 130 is formed by filling a groove for the partition 130 with the conductive part 131 and the insulation part 132. In the replacement processing, a plurality of spaces are formed between the plurality of insulation layers 112 by etching the plurality of sacrificial layers via the groove for the partition 130, and the plurality of conductive layers 111 are formed in the plurality of spaces via the groove for the partition 130.

As described above, as the partition 130 is also used for the replacement processing, a plate-shaped structure that has a structure similar to the partition 130 and extends in a direction perpendicular to the partition 130 (extends within the stacked body 110 in the X-direction and the Z-direction) may be provided in addition to the partition 130.

The lower region 140 is provided at the lower layer side of the stacked body 110, and includes an insulation region 141, a wiring structure 142, a connection electrode 143, and the like. The wiring structure 142 is connected to the pillar structure 120, the conductive layer 111, and the like. Specifically, the wiring structure 142 includes a wiring part extending within the insulation region 141 in a direction parallel to an XY plane surface (a plane surface parallel to the Z-direction), a plug part extending within the insulation region 141 in the Z-direction, and the like. The connection electrode 143 is provided at the first main surface side of the memory chip 100, is directly connected to a connection electrode 223 of the control chip 200, and is used for electrical connection between the wiring structure 142 provided in the memory chip 100 and a wiring structure 222 provided in the control chip 200.

The upper region 150 is provided at the upper layer side of the stacked body 110, and includes a conductive layer 151, an insulation layer 152, and the like. The conductive layer 151 functions as a source region, and is connected to the pillar structure 120 and the partition 130.

The connection region 100b is provided at a position different from that of the memory region 100a where the stacked body 110 is provided when viewed from the Z-direction. The connection region 100b includes a pad portion 160, an extension portion 161, a connection structure 170, the insulation region 141, the wiring structure 142, the connection electrode 143, the insulation layer 152, and the like.

The pad portion 160 is provided at the second main surface side of the memory chip 100, and is used for bonding such as wire-bonding. That is, the pad portion 160 is used as a bonding pad to be connected to a bonding wire or the like, and is made of a conductive material such as a metal material. The pad portion 160 is provided corresponding to the position of the bottom of an opening 152h provided in the insulation layer 152. A center region 160c of the pad portion 160 corresponds to a region to be connected to the bonding wire or the like.

The extension portion 161 extends from the pad portion 160 in a direction parallel to the XY plane surface (a direction parallel to the second main surface of the memory chip 100). That is, the extension portion 161 is provided continuously from the pad portion 160, and is made of the same conductive material as that of the pad portion 160.

The connection structure 170 electrically connects the pad portion 160 and a circuit provided in the control chip 200. In the present embodiment, the connection structure 170 is directly connected to the extension portion 161, and extends within the insulation region 141 in the Z-direction.

The connection structure 170 includes one or more plate-shaped parts 170x extending in the X-direction and the Z-direction and one or more plate-shaped parts 170y extending in the Y-direction and the Z-direction. In the example illustrated in the drawing, the connection structure 170 includes two plate-shaped parts 170x and two plate-shaped parts 170y. The two plate-shaped parts 170x are provided apart from each other, and the two plate-shaped parts 170y are also provided apart from each other. In addition, each plate-shaped part 170x and each plate-shaped part 170y are also provided apart from each other.

Each plate-shaped part 170x includes a conductive part 171 and an insulation part 172 provided along the side surface of the conductive part 171. Therefore, both the conductive part 171 and the insulation part 172 provided in the plate-shaped part 170x extend in the X-direction and the Z-direction. Similarly, each plate-shaped part 170y includes the conductive part 171 and the insulation part 172 provided along the side surface of the conductive part 171. Therefore, both the conductive part 171 and the insulation part 172 provided in the plate-shaped part 170y extend in the Y-direction and the Z-direction.

The connection structure 170 (plate-shaped parts 170x and 170y) is formed in a common process with the partition 130. Therefore, the conductive part 171 of the connection structure 170 is made of the same conductive material as that of the conductive part 131 of the partition 130, and the insulation part 172 of the connection structure 170 is made of the same insulation material as that of the insulation part 132 of the partition 130.

The wiring structure 142 of the connection region 100b is connected between the connection structure 170 and the connection electrode 143. Therefore, the pad portion 160 and the circuit provided in the control chip 200 are electrically connected via the extension portion 161, the connection structure 170, the wiring structure 142, and the connection electrode 143. Similarly to the wiring structure 142 of the memory region 100a, the wiring structure 142 of the connection region 100b also includes the wiring part extending within the insulation region 141 in a direction parallel to the XY plane surface, the plug part extending within the insulation region 141 in the Z-direction, and the like.

The control chip 200 controls the memory operation of the memory chip 100, and includes a semiconductor substrate 210 and a circuit region 220 provided on the semiconductor substrate 210. The circuit region 220 includes an insulation region 221, the wiring structure 222, the connection electrode 223, a CMOS transistor 224, and the like.

The wiring structure 222 is connected to the CMOS transistor 224 and the like, and includes the wiring part extending within the insulation region 221 in a direction parallel to the XY plane surface, the plug part extending within the insulation region 221 in the Z-direction, and the like.

The connection electrode 223 is directly connected to the connection electrode 143 of the memory chip 100, and is used for electrical connection between the wiring structure 222 provided in the control chip 200 and the wiring structure 142 provided in the memory chip 100. Therefore, a memory circuit provided in the memory chip 100, the pad portion 160 and the like are electrically connected to the circuit provided in the control chip 200 via the connection electrode 143 and the connection electrode 223.

As described above, in the present embodiment, the connection structure 170 including the plate-shaped part 170x and the plate-shaped part 170y is formed in the common process with the partition 130. Therefore, similarly to the partition 130, each of the plate-shaped part 170x and the plate-shaped part 170y of the connection structure 170 extends in one direction. As a result, as described below, the resistance of the connection structure 170 can be reduced.

By contrast, if a connection structure is formed in a common process with a contact connected to the conductive layer 111, because the contact has a column-shape, it is difficult to increase the total area (total area seen from the Z-direction) of the connection structure. Therefore, it is difficult to reduce the resistance of the connection structure.

In the present embodiment, each of the plate-shaped part 170x and the plate-shaped part 170y of the connection structure 170 extends in one direction. Therefore, the total area of the whole of the connection structure 170 (total area seen from the Z-direction) can be increased. As a result, the resistance of the connection structure 170 can be reduced, enabling an electrical connection between the circuit provided in the control chip 200 and the pad portion 160 provided in the memory chip 100 that has low resistance.

In the present embodiment, the connection structure 170 is formed in the common process with the partition 130, and thus it is possible to precisely form the connection structure 170 without performing a special process for forming the connection structure 170.

In the present embodiment, the connection structure 170 is directly connected not to the pad portion 160 but to the extension portion 161. Therefore, it is possible to precisely perform bonding to the pad portion 160 without being influenced by the connection structure 170.

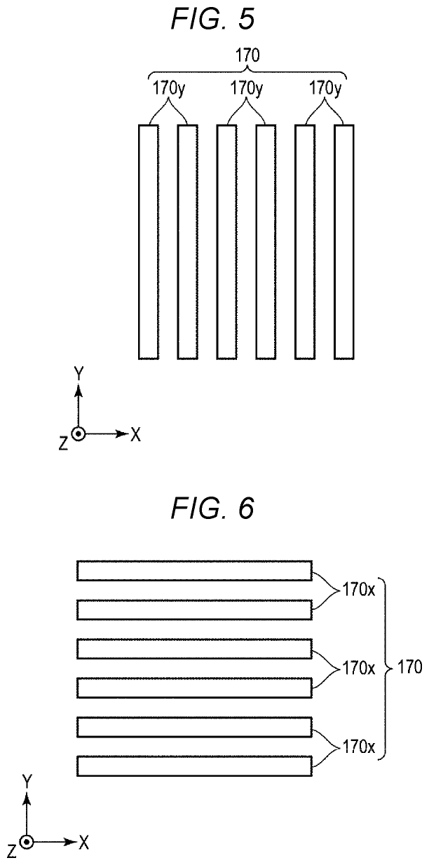

FIG. 5 to FIG. 8 are plane pattern views schematically illustrating various configurations of the connection structure 170 of the semiconductor storage device according to the present embodiment.

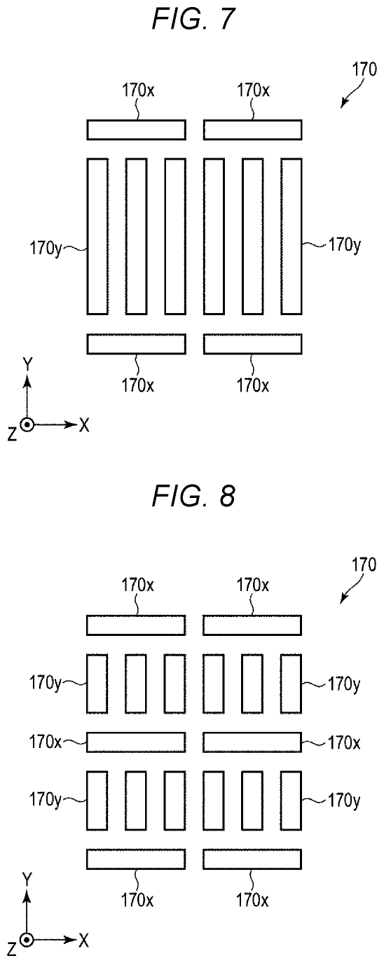

In the configuration of FIG. 5, the connection structure 170 is formed of a plurality of plate-shaped parts 170y each extending in the Y-direction and the Z-direction. In the configuration of FIG. 6, the connection structure 170 is formed of a plurality of plate-shaped parts 170x each extending in the X-direction and the Z-direction. In the configurations of FIG. 7 and FIG. 8, the connection structure 170 is formed of the plurality of plate-shaped parts 170y each extending in the Y-direction and the Z-direction and the plurality of plate-shaped parts 170x each extending in the X-direction and the Z-direction.

As described above, the connection structure 170 may include only one plate-shaped part of one or more plate-shaped parts 170x extending in the X-direction and the Z-direction and one or more plate-shaped parts 170y extending in the Y-direction and the Z-direction. Alternatively, the connection structure 170 may include both plate-shaped parts of one or more plate-shaped parts 170x extending in the X-direction and the Z-direction and one or more plate-shaped parts 170y extending in the Y-direction and the Z-direction.

In the above embodiment and the examples illustrated in FIG. 5 to FIG. 8, the plate-shaped part 170x and the plate-shaped part 170y are provided apart from each other, but the plate-shaped part 170x and the plate-shaped part 170y may be continuously provided.

### Second Embodiment

Next, a second embodiment will be described. The basic matters of the present embodiment are the same as those of the first embodiment, and description of the matters described in the first embodiment will be omitted.

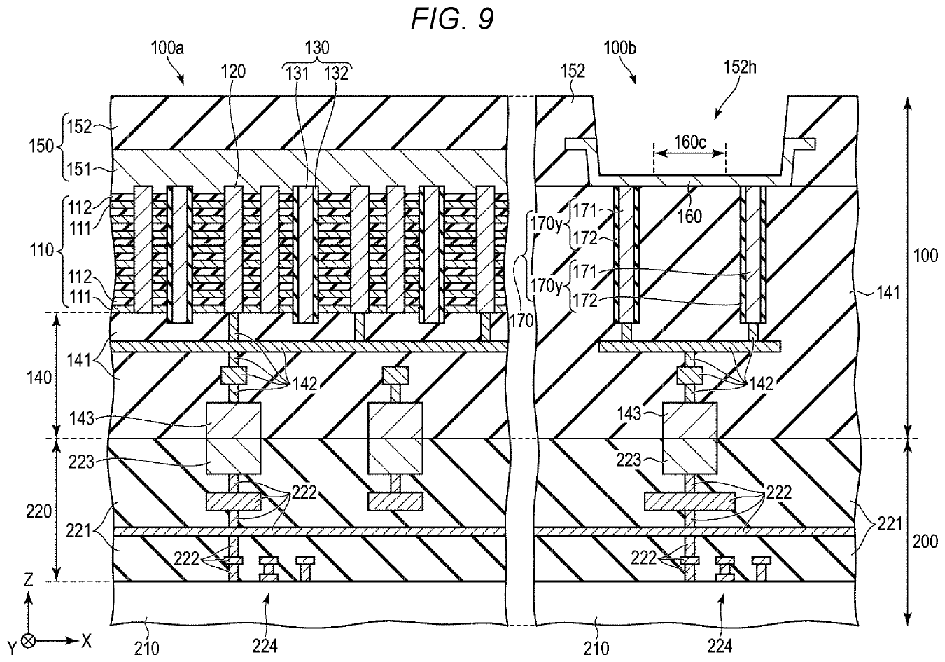

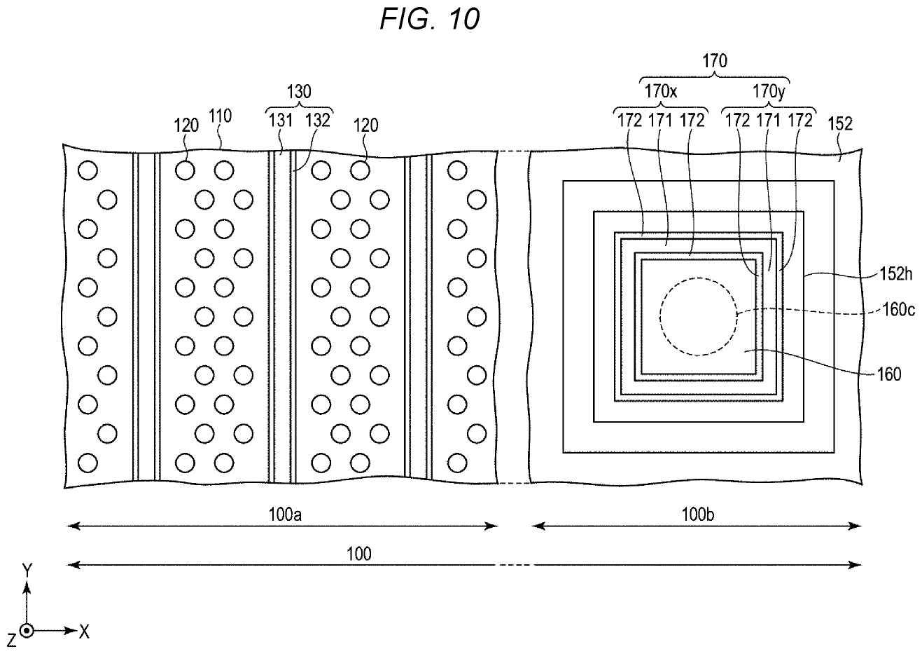

FIG. 9 is a cross-sectional view schematically illustrating a configuration of a NAND-type nonvolatile semiconductor storage device having a three-dimensional structure according to the second embodiment. FIG. 10 is a plane pattern view schematically illustrating a configuration of the memory chip 100 provided in the semiconductor storage device illustrated in FIG. 9 and a plane pattern view of a region corresponding to the region illustrated in FIG. 9.

In the first embodiment, the connection structure 170 is not directly connected to (in contact with) the pad portion 160 and is directly connected to (in contact with) the extension portion 161, but in the present embodiment, the connection structure 170 is directly connected to (in contact with) the pad portion 160.

In the present embodiment, the plate-shaped part 170x and the plate-shaped part 170y are continuously provided, and the connection structure 170 is provided along the outer periphery of the pad portion 160 when viewed from the Z-direction.

The connection structure 170 is not connected to the center region 160c of the pad portion 160 (a region to be connected to a bonding wire or the like), but surrounds the center region 160c when viewed from the Z-direction.

Similarly to the first embodiment, also in the present embodiment, the connection structure 170 including the plate-shaped part 170x and the plate-shaped part 170y is formed in the common process with the partition 130. Therefore, similarly to the first embodiment, each of the plate-shaped part 170x and the plate-shaped part 170y in the connection structure 170 extends in one direction similarly to the partition 130. As a result, also in the present embodiment, it is possible to obtain the same effect as the effect described in the first embodiment.

In the first embodiment, the connection structure 170 is directly connected to the extension portion 161, but in the present embodiment, the connection structure 170 is directly connected to the pad portion 160. Therefore, it is possible to decrease the total area (total area seen from the Z-direction) of the region including the pad portion 160 and the connection structure 170.

In the present embodiment, the connection structure 170 is provided along the outer periphery of the pad portion 160, and is not provided in the center region 160c of the pad portion 160 (a region to be practically connected to a bonding wire or the like). Therefore, it is possible to precisely perform bonding to the pad portion 160 without being influenced by the connection structure 170.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device comprising:
a first chip that has a first main surface and a second main surface and includes memory cells; and
a second chip that is bonded to the first main surface of the first chip and is configured to control operations performed on the memory cells of the first chip, wherein
the first chip includes:
a stacked body including a plurality of conductive layers that are stacked in a first direction;
a plurality of pillar structures that each include a semiconductor layer extending within the stacked body in the first direction;
a plurality of partitions that extend within the stacked body in the first direction and a second direction that intersects with the first direction to divide the stacked body in a third direction that intersects with the first direction and the second direction;
a pad portion that is exposed at the second main surface; and
a connection structure that electrically connects the pad portion and a circuit provided in the second chip, and includes a first plate-shaped part that extends in the first direction and one of the second direction and the third direction.

2. The semiconductor storage device according to claim 1, wherein
the connection structure further includes a second plate-shaped part that extends in the first direction and the other one of the second direction and the third direction.

3. The semiconductor storage device according to claim 2, wherein
the first plate-shaped part and the second plate-shaped part are spaced apart from each other.

4. The semiconductor storage device according to claim 2, wherein
the first plate-shaped part and the second plate-shaped part are continuously provided.

5. The semiconductor storage device according to claim 1, wherein
each of the plurality of partitions includes a first conductive part and a first insulation part that is provided along a side surface of the first conductive part, and
the first plate-shaped part further includes a second conductive part and a second insulation part that is provided along a side surface of the second conductive part.

6. The semiconductor storage device according to claim 1, wherein
the first chip further includes an insulation layer provided at the second main surface side and having an opening through which the pad portion is exposed.

7. The semiconductor storage device according to claim 1, wherein
the first chip further includes an extension portion extending from the pad portion in a direction parallel to the second main surface, and
the connection structure is directly connected to the extension portion.

8. The semiconductor storage device according to claim 1, wherein
the connection structure is directly connected to the pad portion.

9. The semiconductor storage device according to claim 8, wherein
the connection structure is provided along an outer periphery of the pad portion when viewed along the first direction.

10. The semiconductor storage device according to claim 1, wherein
the first chip includes a memory region in which the memory cells are provided and a connection region adjacent to the memory region in the second direction, and
the connection structure extends within an insulation region of the connection region.

11. The semiconductor storage device according to claim 1, wherein
the first chip further includes a connection electrode at the first main surface and connected to the second chip, and a wiring structure connected between the connection structure and the connection electrode, and
the pad portion and the circuit provided in the second chip are electrically connected via the connection structure, the wiring structure, and the connection electrode.

12. The semiconductor storage device according to claim 1, wherein
the stacked body includes the plurality of conductive layers and a plurality of insulation layers that are alternately stacked in the first direction, and the memory cells are formed at intersections of the pillar structures and the conductive layers functioning as word lines.

13. A semiconductor storage device comprising:
a first chip including a plurality of conductive layers and a plurality of insulation layers that are alternately stacked in a first direction and a plurality of semiconductor pillars extending through the stacked conductive and insulation layers, wherein memory cell transistors are formed at intersections of the semiconductor pillars and a group of the conductive layers; and
a second chip that is bonded to a first surface of the first chip and is configured to control operations performed on the memory cell transistors of the first chip, wherein
the first chip further includes a plurality of partitions extending in the first direction and a second direction that intersects with the first direction to divide the stacked conductive and insulation layers in a third direction that intersects with the first direction and the second direction, a bonding pad that is exposed at a second surface of the first chip that is opposite to the first surface, and a connection structure that electrically connects the pad portion and a circuit provided in the second chip and includes a first plate-shaped structure having a plane that is parallel to the third direction.

14. The semiconductor storage device according to claim 13, wherein the connection structure further includes a second plate-shaped structure having a plane that is parallel to the third direction.

15. The semiconductor storage device according to claim 13, wherein the planes of the first and second plate-shaped structures are orthogonal to each other.

16. The semiconductor storage device according to claim 13, wherein
the connection structure further includes a plurality of plate-shaped structures having a plane that is parallel to the third direction, and
the planes of all of the plate-shaped structures including the first plate-shaped structure are parallel to each other.

17. The semiconductor storage device according to claim 13, wherein
the connection structure further includes a plurality of plate-shaped structures having a plane that is parallel to the third direction, and
the planes of all of the plate-shaped structures including the first plate-shaped structure are parallel to the first and second directions or first and third directions.

18. The semiconductor storage device according to claim 13, wherein the connection structure is directly connected to the bonding pad.

19. The semiconductor storage device according to claim 18, wherein the connection structure is directly connected to an outer periphery of the bonding pad.

20. The semiconductor storage device according to claim 13, wherein the connection structure is connected to the bonding pad through a conductive wiring that extends from the bonding pad parallel to the first surface and is in in contact with the connection structure.
